(19) United States
(12) Patent Application Publication
(10) Pub. No.: US 2021/0119421 A1
(43) Pub. Date: Apr. 22, 2021

(54) COLD-START ACCELERATION FOR WAVELENGTH-BEAM-COMBINING LASER RESONATORS

(71) Applicant: PANASONIC INTELLECTUAL PROPERTY MANAGEMENT CO., LTD, Osaka (JP)

(72) Inventors: Wang-Long ZHOU, Andover, MA (US); Bien CHANN, Merrimack, NH (US); Bryan LOCHMAN, Nashville, TN (US); Francisco VILLARREAL-SAUCEDO, Middleton, MA (US)

(21) Appl. No.: 17/068,942

(22) Filed: Oct. 13, 2020

Related U.S. Application Data
(60) Provisional application No. 62/915,767, filed on Oct. 16, 2019.

(51) Int. Cl. H01S 5/40; H01S 5/06; H01S 5/024; B23K 26/50

(52) U.S. Cl. CPC H01S 5/4012; H01S 5/4093; B23K 26/50; H01S 5/02423; H01S 5/0612

(57) ABSTRACT

In various embodiments, cold-start times and performance of wavelength-beam-combining laser resonators are improved via adjustment of the operating wavelengths and/or temperature of beam emitters within the resonators.

### RELATED APPLICATIONS

This application claims the benefit of and priority to U.S. Provisional Patent Application No. 62/915,767, filed Oct. 16, 2019, the entire disclosure of which is hereby incorporated herein by reference.

### TECHNICAL FIELD

In various embodiments, the present invention relates to wavelength-beam-combining laser systems, specifically methods and systems for improving cold-start times for wavelength-beam-combining laser resonators.

### BACKGROUND

High-power laser systems are utilized for a host of different applications, such as welding, cutting, drilling, and materials processing. Such laser systems typically include a laser emitter, the laser light from which is coupled into an optical fiber (or simply a “fiber”), and an optical system that focuses the laser light from the fiber onto the workpiece to be processed. Optical systems for laser systems are typically engineered to produce the highest-quality laser beam, or, equivalently, the beam with the lowest beam parameter product (BPP). The BPP is the product of the laser beam's divergence angle (half-angle) and the radius of the beam at its narrowest point (i.e., the beam waist, the minimum spot size). That is, BPP=NA×D/2, where D is the focusing spot (the waist) diameter and NA is the numerical aperture; thus, the BPP may be varied by varying NA and/or D. The BPP quantifies the quality of the laser beam and how well it can be focused to a small spot, and is typically expressed in units of millimeter-milliradians (mm-mrad). A Gaussian beam has the lowest possible BPP, given by the wavelength of the laser light divided by pi. The ratio of the BPP of an actual beam to that of an ideal Gaussian beam at the same wavelength is denoted M², which is a wavelength-independent measure of beam quality.

Wavelength beam combining (WBC) is a technique for scaling the output power and brightness from laser diodes, laser diode bars, stacks of diode bars, or other lasers arranged in a one- or two-dimensional array. WBC methods have been developed to combine beams along one or both dimensions of an array of emitters. Typical WBC systems include a plurality of emitters, such as one or more diode bars, that are combined using a dispersive element to form a multi-wavelength beam. Each emitter in the WBC system individually resonates, and is stabilized through wavelength-specific feedback from a common partially reflecting output coupler that is filtered by the dispersive element along a beam-combining dimension. Exemplary WBC systems are detailed in U.S. Pat. No. 6,192,062, filed on Feb. 4, 2000, U.S. Pat. No. 6,208,679, filed on Sep. 8, 1998, U.S. Pat. No. 8,670,180, filed on Aug. 25, 2011, and U.S. Pat. No. 8,559,107, filed on Mar. 7, 2011, the entire disclosure of each of which is incorporated by reference herein.

One important metric for evaluating the performance of high-power industrial lasers is the speed at which the laser can begin operating at a desired power level, and remain stable, from a “cold status,” or a “cold start,” i.e., when the laser emitters have not increased in temperature due to operation and are instead at the ambient room temperature or at approximately the temperature of the cooling system (e.g., flowing cooling fluid) in the laser system. WBC direct-diode laser systems combine tens or even hundreds of beams emitted by diode emitters into a single multi-wavelength beam with high beam quality and high power. Diode lasers have intrinsically short rise and fall times (e.g., less than a microsecond), and thus provide advantages to WBC direct-diode systems.

WBC systems lock (via external-cavity feedback) each emitter at a different specific wavelength. Ideally, the locked wavelength of an emitter is located at or near the center of its gain curve when the emitter is operating at high current and concomitantly higher temperature, i.e., at a “hot status,” reached after the emitter has heated up during steady-state operation. However, diode laser gain curves typically shift to longer wavelengths when the laser operation shifts from low current (and/or low temperature) to high current (and/or high temperature), i.e., when the junction temperature of the laser emitter increases from “cold” to “hot.” Since the diode emitters in WBC direct-diode systems are preferably wavelength-locked at their “hot” longer wavelengths, such emitters may become partially or fully unlocked at or during a cold start, because the designated locking wavelength is too far away from the effective region of the “cold” gain curve for the emitter. U.S. Pat. No. 9,190,807, filed on Dec. 16, 2014 (the '807 patent), the entire disclosure of which is incorporated by reference herein, teaches a method to decrease the startup time of WBC direct-diode laser systems by optimizing emitter band regions and their placements. This technique may be quite effective for WBC lasers utilizing emitters emitting at near-infrared or longer wavelengths, because the emitter effective gain bandwidth at such wavelengths is typically wider than the shift of the gain curve when the emitter temperature is increasing from “cold” to “hot.” However, for laser systems utilizing shorter-wavelength emitters, such as those emitting at visible (e.g., blue) or shorter wavelengths, the effective gain bandwidth of the diode emitter may be substantially narrower than the wavelength shift that may occur on startup. For example, for a diode emitter emitting at a nominal wavelength of 405 nm, the gain curve shift at a nominal power of over 2 W may be over 7 nm, which is much larger than the typical gain bandwidth, which may be, for example, about 1 nm at 90% power or less than 4 nm at 50% power. Thus, there is a need for systems and techniques for improving the cold start of, and thereby increasing startup times for, high-power laser systems, particularly those incorporating emitters emitting at shorter wavelengths.

### SUMMARY

Systems and techniques in accordance with embodiments of the present invention improve the cold-start performance of high-power laser systems such as WBC direct-diode systems. In various embodiments, the locking wavelength of individual emitters is altered during operation, enabling the laser system, and the individual emitters, to operate at shorter wavelengths when cold and at longer wavelengths when hot. In additional embodiments, the laser emitters are maintained at a temperature between the cold and hot levels by applying an intermediate current (or, a “simmer current”) to emitters to effectively reduce the wavelength shift during startup. In various embodiments, the applied simmer current is less than the diode threshold current in order to prevent lasing arising from the application of the simmer current. In yet additional embodiments, additional current (or “overdrive current”) beyond the nominal current utilized or required for emitter operation is applied at the cold start to overcome at least a portion of the shortfall in laser power arising from poor cold-start performance and also to increase the temperature of the emitters more quickly. Any two or more of these techniques may be combined in accordance with embodiments of the invention.

In various embodiments, the locking wavelengths of emitters in a WBC laser system are adjusted via adjustment (e.g., rotation) of a folding mirror utilized to redirect the beams toward a partially reflective output coupler. Optical elements such as mirrors may be movable (e.g., translatable and/or rotatable) via use of mechanized stages, gimbals, platforms, and/or mounts, as are known in the art; thus, provision of movable optical elements may be accomplished by those of skill in the art without undue experimentation.

Various WBC laser systems in accordance with embodiments of the invention combine beams emitted by beam emitters (e.g., diode emitters) along a single direction, or dimension, termed the WBC dimension. Accordingly, WBC systems, or “resonators,” often feature their various components lying in the same plane in the WBC dimension. The dimension perpendicular to the WBC dimension, in which the beams are not combined, is typically termed the “non-WBC dimension.” A typical WBC resonator includes a dispersive element (e.g., a diffraction grating) and a downstream feedback surface, which provides (e.g., by reflection) a feedback beam to each corresponding emitter to stabilize the resonator by locking each emitter to its corresponding lasing wavelength. In various embodiments, the resonator wavelength may be tuned (i.e., changed) via rotation of the dispersive element, for example, in embodiments in which the dispersive element includes, consists essentially of, or consists of a reflective diffraction grating.

After laser systems have warmed up from a cold start, with improved cold-start performance as detailed herein, laser systems in accordance with embodiments of the present invention may be utilized to process a workpiece such that the surface of the workpiece is physically altered and/or such that a feature is formed on or within the surface, in contrast with optical techniques that merely probe a surface with light (e.g., reflectivity measurements). Exemplary processes in accordance with embodiments of the invention include cutting, welding, drilling, and soldering. Various embodiments of the invention also process workpieces at one or more spots or along a one-dimensional processing path, rather than simultaneously flooding all or substantially all of the workpiece surface with radiation from the laser beam. In general, processing paths may be curvilinear or linear, and “linear” processing paths may feature one or more directional changes, i.e., linear processing paths may be composed of two or more substantially straight segments that are not necessarily parallel to each other.

Various embodiments of the invention may be utilized with laser systems featuring techniques for varying BPP of their output laser beams, such as those described in U.S. patent application Ser. No. 14/632,283, filed on Feb. 26, 2015, and U.S. patent application Ser. No. 15/188,076, filed on Jun. 21, 2016, the entire disclosure of each of which is incorporated herein by reference.

Herein, “optical elements” may refer to any of lenses, mirrors, prisms, gratings, and the like, which redirect, reflect, bend, or in any other manner optically manipulate electromagnetic radiation, unless otherwise indicated. Herein, beam emitters, emitters, or laser emitters, or lasers include any electromagnetic beam-generating device such as semiconductor elements, which generate an electromagnetic beam, but may or may not be self-resonating. These also include fiber lasers, disk lasers, non-solid state lasers, etc. Generally, each emitter includes a back reflective surface, at least one optical gain medium, and a front reflective surface. The optical gain medium increases the gain of electromagnetic radiation that is not limited to any particular portion of the electromagnetic spectrum, but that may be visible, infrared, and/or ultraviolet light. An emitter may include or consist essentially of multiple beam emitters such as a diode bar configured to emit multiple beams. The input beams received in the embodiments herein may be single-wavelength or multi-wavelength beams combined using various techniques known in the art. Herein, it is understood that references to different “wavelengths” encompass different “ranges of wavelengths,” and the wavelength (or color) of a laser corresponds to the primary wavelength thereof; that is, emitters may emit light having a finite band of wavelengths that includes (and may be centered on) the primary wavelength.

Laser systems in accordance with various embodiments of the present invention may also include a delivery mechanism that directs the laser output onto the workpiece while causing relative movement between the output and the workpiece. For example, the delivery mechanism may include, consist essentially of, or consist of a laser head for directing and/or focusing the output toward the workpiece. The laser head may itself be movable and/or rotatable relative to the workpiece, and/or the delivery mechanism may include a movable gantry or other platform for the workpiece to enable movement of the workpiece relative to the output, which may be fixed in place.

In various embodiments of the present invention, the laser beams utilized for processing of various workpieces may be delivered to the workpiece via one or more optical fibers (or “delivery fibers”). Embodiments of the invention may incorporate optical fibers having many different internal configurations and geometries. Such optical fibers may have one or more core regions and one or more cladding regions. For example, the optical fiber may include, consist essentially of, or consist of a central core region and an annular core region separated by an inner cladding layer. One or more outer cladding layers may be disposed around the annular core region. Embodiments of the invention may be utilized with and/or incorporate optical fibers having configurations described in U.S. patent application Ser. No. 15/479,745, filed on Apr. 5, 2017, and U.S. patent application Ser. No. 16/675,655, filed on Nov. 6, 2019, the entire disclosure of each of which is incorporated by reference herein.

Structurally, optical fibers in accordance with embodiments of the invention may include one or more layers of high and/or low refractive index beyond (i.e., outside of) an exterior cladding without altering the principles of the present invention. Various ones of these additional layers may also be termed claddings or coatings, and may not guide light. Optical fibers may also include one or more cores in addition to those specifically mentioned. Such variants are within the scope of the present invention. Various embodiments of the invention do not incorporate mode strippers in or on the optical fiber structure. Similarly, the various layers of optical fibers in accordance with embodiments of the invention are continuous along the entire length of the fiber and do not contain holes, photonic-crystal structures, breaks, gaps, or other discontinuities therein.

Optical fibers in accordance with the invention may be multi-mode fibers and therefore support multiple modes therein (e.g., more than three, more than ten, more than 20, more than 50, or more than 100 modes). In addition, optical fibers in accordance with the invention are generally passive fibers, i.e., are not doped with active dopants (e.g., erbium, ytterbium, thulium, neodymium, dysprosium, praseodymium, holmium, or other rare-earth metals) as are typically utilized for pumped fiber lasers and amplifiers. Rather, dopants utilized to select desired refractive indices in various layers of fibers in accordance with the present invention are generally passive dopants that are not excited by laser light, e.g., fluorine, titanium, germanium, and/or boron. Thus, optical fibers, and the various core and cladding layers thereof in accordance with various embodiments of the invention may include, consist essentially of, or consist of glass, such as substantially pure fused silica and/or fused silica, and may be doped with fluorine, titanium, germanium, and/or boron. Obtaining a desired refractive index for a particular layer or region of an optical fiber in accordance with embodiments of the invention may be accomplished (by techniques such as doping) by one of skill in the art without undue experimentation. Relatedly, optical fibers in accordance with embodiments of the invention may not incorporate reflectors or partial reflectors (e.g., grating such as Bragg gratings) therein or thereon. Fibers in accordance with embodiments of the invention are typically not pumped with pump light configured to generate laser light of a different wavelength. Rather, fibers in accordance with embodiments of the invention merely propagate light along their lengths without changing its wavelength. Optical fibers utilized in various embodiments of the invention may feature an optional external polymeric protective coating or sheath disposed around the more fragile glass or fused silica fiber itself.

In addition, systems and techniques in accordance with embodiments of the present invention are typically utilized for materials processing (e.g., cutting, drilling, etc.), rather than for applications such as optical communication or optical data transmission. Thus, laser beams, which may be coupled into fibers in accordance with embodiments of the invention, may have wavelengths different from the 1.3 μm or 1.5 μm utilized for optical communication. In fact, fibers utilized in accordance with embodiments of the present invention may exhibit dispersion at one or more (or even all) wavelengths in the range of approximately 1260 nm to approximately 1675 nm utilized for optical communication.

In an aspect, embodiments of the invention feature a method of operating a wavelength-beam-combining (WBC) resonator while improving startup time from cold start. The WBC resonator includes an emitter having (i) a gain bandwidth defining a range of operating wavelengths at which a gain of the emitter exceeds a predetermined effective gain level, and (ii) a nominal operating wavelength (a) falling within the gain bandwidth at an operating temperature and (b) falling outside of the gain bandwidth at a startup temperature lower than the operating temperature. The emitter is provided, the emitter having a temperature equal to the startup temperature. Heat is applied to the emitter to increase the temperature thereof. Thereafter, the emitter is operated to emit a beam at the nominal operating wavelength, whereby the temperature of the emitter increases to the operating temperature during operation.

Embodiments of the invention may include one or more of the following in any of a variety of combinations. Operating the emitter may include, consist essentially of, or consist of applying to the emitter a current greater than a lasing threshold current of the emitter. Applying heat to the emitter may include, consist essentially of, or consist of applying to the emitter a simmer current less than the lasing threshold current. Applying heat to the emitter may include, consist essentially of, or consist of locally heating the emitter via a heat source external to the emitter (i.e., a source of heat beyond heat generated by the emitter itself during operation). The heat source may include, consist essentially of, or consist of a resistive heater, an infrared heater, and/or a thermoelectric heater. The nominal operating wavelength of the emitter may be a wavelength of visible light or ultraviolet light. The nominal operating wavelength of the emitter may be a wavelength of blue light. The startup temperature may be approximately equal to a temperature of an ambient environment in which the WBC resonator is disposed. The WBC resonator may include a cooling system utilizing a fluid coolant. The startup temperature may be approximately equal to a temperature of the fluid coolant, which may be higher or lower than the temperature of the ambient environment.

The WBC resonator may include a plurality of additional emitters each having a nominal operating wavelength different from the nominal operating wavelength of the emitter, a dispersive element configured to receive beams emitted by the emitter and the plurality of additional emitters and combine the beams into a multi-wavelength beam, and disposed optically downstream of the dispersive element, a partially reflective output coupler configured to (i) receive the multi-wavelength beam, (ii) transmit a first portion of the multi-wavelength beam from the WBC resonator as an output beam, and (iii) reflect a second portion of the multi-wavelength beam back toward the dispersive element. The beam emitted by the emitter may be combined, within the WBC resonator, with beams emitted by a plurality of additional emitters, to thereby form a multi-wavelength beam. A first portion of the multi-wavelength beam may be transmitted from the WBC resonator as an output beam. A second portion of the multi-wavelength beam may be propagated (e.g., reflected) back to the emitter and the plurality of additional emitters to stabilize the beams (e.g., the wavelengths of the beams) emitted by the emitter and by the plurality of additional emitters. Heat may be applied to the plurality of additional emitters to increase a temperature thereof. Thereafter, the plurality of additional emitters may be operated to emit beams therefrom. A workpiece may be processed with the output beam. Processing the workpiece may include, consist essentially of, or consist of cutting, welding, etching, annealing, drilling, soldering, and or brazing. Processing the workpiece may include, consist essentially of, or consist of physically altering at least a portion of a surface of the workpiece.

In another aspect, embodiments of the invention include a method of operating a wavelength-beam-combining (WBC) resonator while improving startup time from cold start. The WBC resonator includes an emitter having (i) a gain bandwidth defining a range of operating wavelengths at which a gain of the emitter exceeds a predetermined effective gain level, and (ii) a nominal operating wavelength (a) falling within the gain bandwidth at an operating temperature and (b) falling outside of the gain bandwidth at a startup temperature lower than the operating temperature. The emitter is operable at a nominal drive current greater than a lasing threshold current to produce a beam having the nominal operating wavelength. Operation of the emitter is initiated, at the startup temperature, by applying to the emitter an overdrive current greater than the nominal drive current. When or while a temperature of the emitter increases to the operating temperature, the applied current is decreased to the nominal drive current.

Embodiments of the invention may include one or more of the following in any of a variety of combinations. The applied current may be decreased gradually from the overdrive current to the nominal drive current as the temperature of the emitter increases to the operating temperature. Before initiating operation of the emitter, heat may be applied to the emitter to increase the temperature thereof. Applying heat to the emitter may include, consist essentially of, or consist of applying to the emitter a simmer current less than the lasing threshold current. Applying heat to the emitter may include, consist essentially of, or consist of locally heating the emitter via a heat source external to the emitter (i.e., a source of heat beyond heat generated by the emitter itself during operation). The heat source may include, consist essentially of, or consist of a resistive heater, an infrared heater, and/or a thermoelectric heater. The nominal operating wavelength of the emitter may be a wavelength of visible light or ultraviolet light. The nominal operating wavelength of the emitter may be a wavelength of blue light.

The WBC resonator may include a plurality of additional emitters each having a nominal operating wavelength different from the nominal operating wavelength of the emitter, a dispersive element configured to receive beams emitted by the emitter and the plurality of additional emitters and combine the beams into a multi-wavelength beam, and disposed optically downstream of the dispersive element, a partially reflective output coupler configured to (i) receive the multi-wavelength beam, (ii) transmit a first portion of the multi-wavelength beam from the WBC resonator as an output beam, and (iii) reflect a second portion of the multi-wavelength beam back toward the dispersive element. The beam emitted by the emitter may be combined, within the WBC resonator, with beams emitted by a plurality of additional emitters, to thereby form a multi-wavelength beam. A first portion of the multi-wavelength beam may be transmitted from the WBC resonator as an output beam. A second portion of the multi-wavelength beam may be propagated (e.g., reflected) back to the emitter and the plurality of additional emitters to stabilize the beams (e.g., the wavelengths of the beams) emitted by the emitter and by the plurality of additional emitters. A workpiece may be processed with the output beam. Processing the workpiece may include, consist essentially of, or consist of cutting, welding, etching, annealing, drilling, soldering, and or brazing. Processing the workpiece may include, consist essentially of, or consist of physically altering at least a portion of a surface of the workpiece.

In yet another aspect, embodiments of the invention feature a method of operating a wavelength-beam-combining (WBC) resonator while improving startup time from cold start. The WBC resonator includes an emitter having a gain bandwidth defining a range of operating feedback-locked wavelengths at which a gain of the emitter exceeds a predetermined effective gain level. The operating wavelengths within the gain bandwidth increase as a function of increasing operating temperature of the emitter. The emitter has a nominal operating wavelength (a) falling within the gain bandwidth at an operating temperature and (b) falling outside of the gain bandwidth at a startup temperature lower than the operating temperature. The emitter is provided, a temperature of the emitter being equal to the startup temperature. An operating wavelength of the emitter is initially configured to fall within the gain bandwidth at the startup temperature. Thereafter, the emitter is operated by applying a drive current thereto. During operation of the emitter, the operating wavelength of the emitter is increased as the temperature of the emitter increases such that, when the temperature of the emitter is equal to the operating temperature, the operating wavelength of the emitter is equal to the nominal operating wavelength.

Embodiments of the invention may include one or more of the following in any of a variety of combinations. The operating wavelength of the emitter may be increased to the nominal operating wavelength in one or more discrete steps during operation of the emitter. The operating wavelength of the emitter may be increased to the nominal operating wavelength gradually (e.g., continuously) during operation of the emitter. The WBC resonator may include (A) a dispersive element configured to receive one or more beams from the emitter and combine the one or more beams with one or more beams received from one or more other emitters disposed in the WBC resonator, thereby forming a multi-wavelength beam, (B) a folding mirror disposed optically downstream of the emitter, and (C) disposed optically downstream of the dispersive element, a partially reflective output coupler configured to (i) receive the multi-wavelength beam, (ii) transmit a first portion of the multi-wavelength beam from the WBC resonator as an output beam, and (iii) reflect a second portion of the multi-wavelength beam back toward the dispersive element. The operating wavelength of the emitter may be initially configured, at least in part, by selecting a rotation angle of the folding mirror. Increasing the operating wavelength of the emitter during operation of the emitter may include, consist essentially of, or consist of rotating the folding mirror. An axis of rotation of the folding mirror may be changed during rotation of the folding mirror. Neither a position nor a rotation angle of the output coupler may be changed during rotation of the folding mirror. The multi-wavelength beam may strike the output coupler at an angle perpendicular to a surface of the output coupler, notwithstanding rotation of the folding mirror. The folding mirror may be disposed optically upstream or optically downstream of the dispersive element. The WBC resonator may include, disposed optically downstream of the dispersive element, a telescopic lens pair for reducing a size of the multi-wavelength beam. A workpiece may be processed with the output beam. Processing the workpiece may include, consist essentially of, or consist of cutting, welding, etching, annealing, drilling, soldering, and or brazing. Processing the workpiece may include, consist essentially of, or consist of physically altering at least a portion of a surface of the workpiece. The nominal operating wavelength of the emitter may be a wavelength of visible light or ultraviolet light. The nominal operating wavelength of the emitter may be a wavelength of blue light.

The beam emitted by the emitter may be combined, within the WBC resonator, with beams emitted by a plurality of additional emitters, to thereby form a multi-wavelength beam. A first portion of the multi-wavelength beam may be transmitted from the WBC resonator as an output beam. A second portion of the multi-wavelength beam may be propagated (e.g., reflected) back to the emitter and the plurality of additional emitters to stabilize the beams (e.g., the wavelengths of the beams) emitted by the emitter and by the plurality of additional emitters. A workpiece may be processed with the output beam. Processing the workpiece may include, consist essentially of, or consist of cutting, welding, etching, annealing, drilling, soldering, and or brazing. Processing the workpiece may include, consist essentially of, or consist of physically altering at least a portion of a surface of the workpiece.

In another aspect, embodiments of the invention include a method of operating a wavelength-beam-combining (WBC) resonator. The WBC resonator includes, consists essentially of, or consists of (a) a plurality of emitters each configured to emit one or more beams, (b) a dispersive element configured to receive the beams and disperse the received beams to generate a multi-wavelength beam, (c) a folding mirror, and (d) a partially reflective output coupler configured to (i) receive the multi-wavelength beam, (ii) transmit a first portion of the multi-wavelength beam from the WBC resonator as an output beam, and (iii) reflect a second portion of the multi-wavelength beam back toward the dispersive element. The plurality of emitters is operated by applying a drive current thereto. Thereduring, the folding mirror is rotated, whereby an operating wavelength of one or more of the emitters is changed.

Embodiments of the invention may include one or more of the following in any of a variety of combinations. An axis of rotation of the folding mirror may be changed during rotation of the folding mirror, whereby a shift of a position on the output coupler at which the multi-wavelength beam is received due to rotation of the folding mirror is reduced or eliminated. Neither a position nor a rotation angle of the output coupler may be changed during rotation of the folding mirror. The multi-wavelength beam may strike the output coupler at an angle perpendicular to a surface of the output coupler, notwithstanding rotation of the folding mirror. The folding mirror may be disposed optically upstream or optically downstream of the dispersive element. The WBC resonator may include, disposed optically downstream of the dispersive element, a telescopic lens pair for reducing a size of the multi-wavelength beam. One or more of the emitters may be configured to emit visible light or ultraviolet light. One or more of the emitters may be configured to emit blue light. A workpiece may be processed with the output beam. Processing the workpiece may include, consist essentially of, or consist of cutting, welding, etching, annealing, drilling, soldering, and or brazing. Processing the workpiece may include, consist essentially of, or consist of physically altering at least a portion of a surface of the workpiece.

In yet another aspect, embodiments of the invention feature a wavelength-beam-combining (WBC) resonator including, consisting essentially of, or consisting of (A) a plurality of emitters each configured to emit one or more beams, (B) a dispersive element configured to receive the beams and disperse the received beams to generate a multi-wavelength beam, (C) a partially reflective output coupler configured to (i) receive the multi-wavelength beam, (ii) transmit a first portion of the multi-wavelength beam from the WBC resonator as an output beam, and (iii) reflect a second portion of the multi-wavelength beam back toward the dispersive element, and (D) a controller configured to preheat one or more of the emitters prior to emission of the one or more beams thereby.

Embodiments of the invention may include one or more of the following in any of a variety of combinations. The resonator may include a power source configured to supply current to the plurality of emitters for operation thereof. The controller may be configured to preheat one or more of the emitters by supplying thereto a simmer current. The simmer current may be less than a lasing threshold current of the one or more emitters. The resonator may include a heat source configured to heat the one or more emitters. The controller may be configured to preheat one or more of the emitters by operating the heat source. The heat source may include, consist essentially of, or consist of a resistive heater, an infrared heater, and/or a thermoelectric heater. The controller may be configured to not apply additional heat (e.g., heat beyond heat generated by the one or more emitters themselves) to the one or more emitters after a temperature of the one or more emitters has increased to a nominal operating temperature. At least one emitter may be configured to emit visible light or ultraviolet light. At least one emitter may be configured to emit blue light. The resonator may include, disposed optically downstream of the dispersive element, a telescopic lens pair for reducing a size of the multi-wavelength beam.

In another aspect, embodiments of the invention feature a wavelength-beam-combining (WBC) resonator including, consisting essentially of, or consisting of (A) a plurality of emitters each (i) configured to emit one or more beams and (ii) operable at a nominal drive current greater than a lasing threshold current to emit the one or more beams, (B) a dispersive element configured to receive the beams and disperse the received beams to generate a multi-wavelength beam, (C) a partially reflective output coupler configured to (i) receive the multi-wavelength beam, (ii) transmit a first portion of the multi-wavelength beam from the WBC resonator as an output beam, and (iii) reflect a second portion of the multi-wavelength beam back toward the dispersive element, (D) a power source configured to supply drive current to the plurality of emitters for operation thereof, and (E) a controller configured to (i) initiate operation of one or more of the emitters, prior to emission of the one or more beams thereby, by applying to the one or more of the emitters an overdrive current greater than the nominal drive current thereof, and (ii) when a temperature of the one or more emitters increases to an operating temperature, decreasing the applied current to the nominal drive current.

Embodiments of the invention may include one or more of the following in any of a variety of combinations. The controller may be configured to preheat one or more of the emitters, prior to emission of the one or more beams thereby, by applying thereto a simmer current less than the lasing threshold current. The resonator may include a heat source configured to heat the one or more emitters. The controller may be configured to preheat one or more of the emitters, prior to emission of the one or more beams thereby, by operating the heat source. The heat source may include, consist essentially of, or consist of a resistive heater, an infrared heater, and/or a thermoelectric heater. The controller may be configured to not apply additional heat to the one or more emitters after a temperature of the one or more emitters has increased to the operating temperature. At least one emitter may be configured to emit visible light or ultraviolet light. At least one emitter may be configured to emit blue light. The resonator may include, disposed optically downstream of the dispersive element, a telescopic lens pair for reducing a size of the multi-wavelength beam.

In yet another aspect, embodiments of the invention feature a wavelength-beam-combining (WBC) resonator including, consisting essentially of, or consisting of (A) a plurality of emitters each configured to emit one or more beams, (B) a dispersive element configured to receive the beams and disperse the received beams to generate a multi-wavelength beam, (C) a partially reflective output coupler configured to (i) receive the multi-wavelength beam, (ii) transmit a first portion of the multi-wavelength beam as an output beam, and (iii) reflect a second portion of the multi-wavelength beam back toward the dispersive element, (D) a folding mirror disposed optically downstream of the plurality of emitters, and (E) a controller configured to rotate the folding mirror during operation of the plurality of emitters.

Embodiments of the invention may include one or more of the following in any of a variety of combinations. The controller may be configured to change an axis of rotation of the folding mirror during rotation thereof. The resonator may include one or more actuators, responsive to the controller, for rotating the folding mirror. The folding mirror may be disposed optically upstream of or optically downstream of the dispersive element. At least one emitter may be configured to emit visible light or ultraviolet light. At least one emitter may be configured to emit blue light. The resonator may include, disposed optically downstream of the dispersive element, a telescopic lens pair for reducing a size of the multi-wavelength beam. The controller may be configured to preheat one or more of the emitters prior to emission of the one or more beams thereby. The resonator may include a power source configured to supply current to the plurality of emitters for operation thereof. The controller may be configured to preheat one or more of the emitters by supplying thereto a simmer current. The simmer current may be less than a lasing threshold current of the one or more emitters. The resonator may include a heat source configured to heat the one or more emitters. The controller may be configured to preheat one or more of the emitters by operating the heat source. The heat source may include, consist essentially of, or consist of a resistive heater, an infrared heater, and/or a thermoelectric heater. The controller may be configured to not apply additional heat to the one or more emitters after a temperature of the one or more emitters has increased to a nominal operating temperature. The resonator may include a power source configured to supply current to the plurality of emitters for operation thereof. The controller may be configured to (i) initiate operation of one or more of the emitters, prior to emission of the one or more beams thereby, by applying to the one or more of the emitters an overdrive current greater than a nominal drive current thereof, and (ii) when a temperature of the one or more emitters increases to an operating temperature, decrease the applied current to the nominal drive current.

These and other objects, along with advantages and features of the present invention herein disclosed, will become more apparent through reference to the following description, the accompanying drawings, and the claims. Furthermore, it is to be understood that the features of the various embodiments described herein are not mutually exclusive and may exist in various combinations and permutations. As used herein, the term “substantially” means±10%, and in some embodiments, ±5%. The term “consists essentially of” means excluding other materials that contribute to function, unless otherwise defined herein. Nonetheless, such other materials may be present, collectively or individually, in trace amounts. Herein, the terms “radiation” and “light” are utilized interchangeably unless otherwise indicated. Herein, “downstream” or “optically downstream,” is utilized to indicate the relative placement of a second element that a light beam strikes after encountering a first element, the first element being “upstream,” or “optically upstream” of the second element. Herein, “optical distance” between two components is the distance between two components that is actually traveled by light beams; the optical distance may be, but is not necessarily, equal to the physical distance between two components due to, e.g., reflections from mirrors or other changes in propagation direction experienced by the light traveling from one of the components to the other. Distances utilized herein may be considered to be “optical distances” unless otherwise specified.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1A is a graph of exemplary cold and hot gain curves, and their overlap, for an emitter having a finite positive working range in accordance with embodiments of the present invention;

FIG. 1B is a graph of exemplary cold and hot gain curves, and their overlap, for an emitter having zero working range in accordance with embodiments of the present invention;

FIG. 1C is a graph of exemplary cold and hot gain curves, with no meaningful overlap, for an emitter in accordance with embodiments of the present invention;

FIGS. 2A-2C schematically depict techniques for improving the cold-start performance of emitters exhibiting the behavior depicted in FIG. 1B via application of simmer current (FIG. 2A), application of overdrive current (FIG. 2B), or both (FIG. 2C), in accordance with embodiments of the present invention;

FIG. 3 schematically depicts a technique for improving the cold-start performance of emitters in which the emitter operating wavelength is actively changed during operation, in accordance with embodiments of the present invention;

FIG. 4 is a schematic diagram of a wavelength beam combining (WBC) resonator in accordance with embodiments of the present invention;

FIG. 5 is a graph of simulated wavelength and position shifts of a resonator output beam as a function of the rotation angle of a folding mirror in accordance with embodiments of the present invention;

FIG. 6A schematically depicts the effect of folding mirror rotation on beam position in accordance with embodiments of the present invention;

FIG. 6B schematically depicts the reduction of beam shift of an output beam via movement of the folding mirror rotation axis in accordance with embodiments of the present invention; and

FIGS. 7A-7C are graphs schematically depicting the relationship between resonator wavelength and emitter wavelength from cold start in accordance with various embodiments of the present invention.

### DETAILED DESCRIPTION

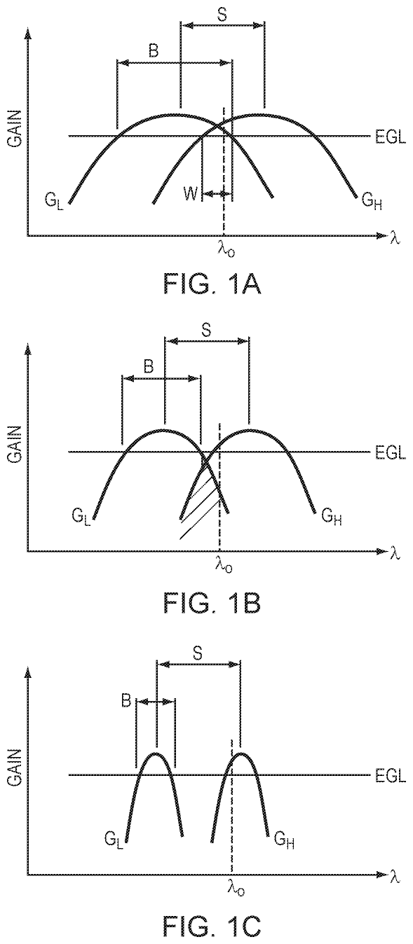

FIG. 1A is a graph of exemplary cold and hot gain curves, and their overlap, for a diode emitter. In FIG. 1A and later figures, G_{L} refers to the gain curve at “cold status,” i.e., low temperature (e.g., the temperature at startup), while G_{H} refers to the gain curve at “hot status,” i.e., high temperature (e.g., during sustained operation). B refers to the gain bandwidth, which is the width of the gain curve at the effective gain level (EGL) of the emitter, which is typically at 90% gain or higher. S refers to the shift in wavelength (λ) of the gain curve experienced in the transition from cold status to hot status.

In the example of FIG. 1A, the gain bandwidth S is larger than the wavelength shift S, resulting in a finite positive working range W, which is equal to the difference between B and S. An emitter locked to a wavelength within the range W, for example at the depicted wavelength λ₀, will have a fast rising time because it will generate power at cold status at a level comparable to that generated at hot status. Example emitters exhibiting such behavior include at least some semiconductor laser emitters emitting at near-infrared or longer wavelengths. Techniques disclosed in the '807 patent may be successfully applied to such emitters to increase the width of the range W and therefore improve laser performance.

In the example of FIG. 1B, the gain bandwidth B is narrower than the wavelength shift S, resulting in zero working range above the effective gain level EGL. However, the cold and hot gain curves still do overlap at gain levels lower than EGL but at meaningful gain levels, represented by the shaded area in FIG. 1B. In the example of FIG. 1B, an emitter locked to wavelength λ₀, which is near the optimized point of the hot gain curve, will not produce sufficient power at cold status. Therefore, a laser system incorporating such emitters will rise more slowly at cold start and require more time to reach sustained stable operation.

In the example of FIG. 1C, the gain bandwidth B is substantially narrower than the wavelength shift S, resulting in no meaningful overlap of the cold and hot gain curves. Emitters exhibiting such behavior include various diode lasers emitting at visible (e.g., blue, blue-violet, violet) wavelengths and/or ultraviolet wavelengths. In such cases, at emitter locked at a hot wavelength λ₀ will be fully wavelength-unlocked at cold start, and therefore may produce little or no power at cold start, resulting in a much slower rise time to sustained stable operation. For simplicity, it is assumed that emitter drive currents may be raised instantaneously from zero to a preset operating current. As such, “cold status” refers to a low temperature of the emitter (typically the ambient room temperature or the temperature of cooling fluid utilized in the laser system), rather than low current levels.

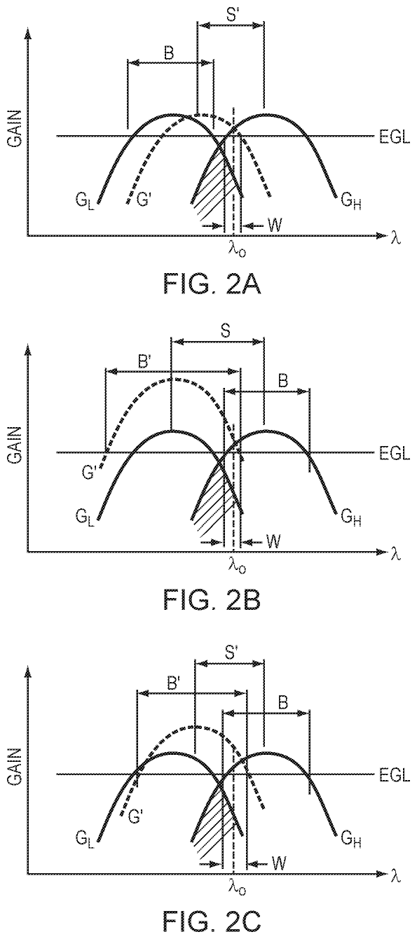

FIGS. 2A-2C schematically depict techniques for improving the cold-start performance of emitters exhibiting the behavior depicted in FIG. 1B via application of simmer current (FIG. 2A), application of overdrive current (FIG. 2B), or both (FIG. 2C). By applying simmer current, an emitter may be preheated and thus be cold started from a higher temperature. In FIG. 2A, the dashed curve G′ represents the gain curve of such a preheated emitter. As shown, with a preheated emitter, the resulting wavelength shift S′ in the transition to hot status may be smaller than the gain bandwidth B, resulting in a finite positive working range W (equal to the difference of B and S′). In various embodiments, the applied simmer current is limited to a level below the laser threshold current of the emitter; thus, in various embodiments the amount of resulting heat applied to the emitter may be limited. In various embodiments, instead of or in addition to applying a simmer current to the emitter, a local heater or heat source (e.g., an infrared heater, a resistive heater, and/or a thermoelectric cooler/heater may be utilized to heat one or more emitters in the laser system. The local heat source may apply heat to the emitter(s) at (and/or before) cold start and then be gradually or immediately switched off once cold start has been initiated. In various embodiments, the local heat source may be abruptly turned off once the emitter has achieved hot status and the concomitant elevated operating temperature. In various embodiments, the heat applied by the local heat source may be gradually decreased as the operating temperature of the emitter increases due to the operating current utilized thereby; in such embodiments, the local heat source may be turned off once the emitter has reached hot status and its operating temperature.

FIG. 2B schematically depicts an embodiment of the invention in which overdrive (or “overshoot”) current is applied to the emitter to effectively increase the gain level at cold start. As shown, the emitter gain curve G′ is shifted higher, resulting in a wider gain bandwidth B′ at EGL. For simplicity, assuming that the overdrive current is decreased linearly back to the nominal operating current during the transition from cold to hot operation, the resulting working range W may be calculated by W=(B′+B)/2−S. Since B is less than S, embodiments of the invention apply a sufficient overdrive current such that (B′+B)/2 is greater than S.

FIG. 2C schematically depicts embodiments in which both simmer current (and/or local heating) and overdrive current are applied to the emitter to achieve faster cold-start performance. Again assuming a linear decrease of the overdrive current back to the nominal operating current during the transition from cold to hot operation, the resulting working range W may be calculated by W=(B′+B)/2−S′. In various embodiments, because diode emitters may become less efficient (and thus run at hotter temperatures) over their working lifetimes, the working range W achieved utilizing the above methods may be increased to compensate.

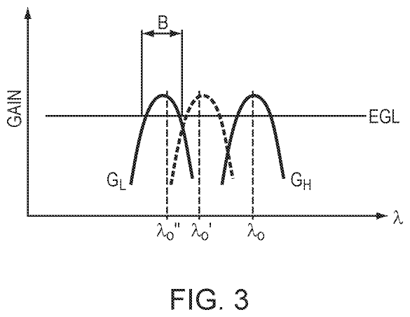

FIG. 3 schematically depicts embodiments of the invention in which the emitter operating (i.e., locked) wavelength is actively changed during operation, a technique which may be applied to emitters exhibiting any of the behaviors depicted in FIGS. 1A-1C. However, such embodiments may be particularly applicable to emitters exhibiting the behavior depicted in FIG. 1C (e.g., emitters configured to emit visible (e.g., blue, blue-violet, violet) or ultraviolet wavelengths). As shown in FIG. 3, the emitter operating wavelength is changed (e.g., increased) from λ₀″ at cold status (i.e., at and/or before startup), to λ₀′ at an intermediate status where the temperature of the emitter is between the low temperature at cold status and the high temperature at hot status, and finally to λ₀ at hot status (i.e., where the temperature of the emitter has stabilized at its higher operating temperature). In such embodiments, the impact of the gain curve shift at cold start is effectively eliminated, and the resulting working range W is equal to the gain bandwidth B. Such embodiments of the invention are additionally advantageous because the operating wavelength may be continually set at or near the peak of the gain curve at each temperature, resulting in high power efficiency of the laser system.

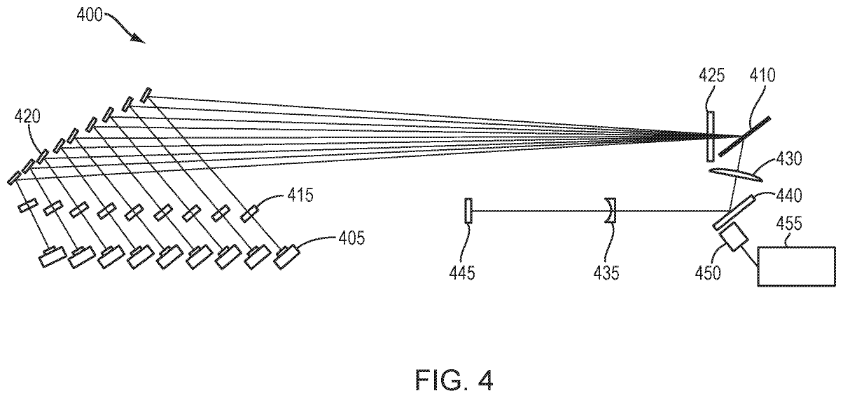

FIG. 4 schematically depicts a system and technique for adjusting the emitter operating wavelength in a WBC resonator in accordance with the embodiments depicted in FIG. 3. FIG. 4 schematically depicts various components of a WBC resonator 400 that, in the depicted embodiment, combines the beams emitted by nine different multi-beam emitters, i.e., emitters from which multiple beams are emitted from a single package, such as diode bars. Embodiments of the invention may be utilized with fewer or more than nine emitters. In accordance with embodiments of the invention, each emitter may emit a single beam, or, each of the emitters may emit multiple beams. The emitters in FIG. 4 are depicted as each emitting a single beam for clarity and convenience of illustration. The view of FIG. 4 is along the WBC dimension, i.e., the dimension in which the beams from the bars are combined. The exemplary resonator 400 features nine diode bars 405, and each diode bar 405 includes, consists essentially of, or consists of an array (e.g., one-dimensional array) of emitters along the WBC dimension. Each emitter of a diode bar 405 may emit a non-symmetrical beam having a larger divergence in one direction (known as the “fast axis,” here oriented vertically relative to the WBC dimension) and a smaller divergence in the perpendicular direction (known as the “slow axis,” here along the WBC dimension).

In various embodiments, each of the diode bars 405 is associated with (e.g., attached or otherwise optically coupled to) a fast-axis collimator (FAC)/optical twister microlens assembly that collimates the fast axis of the emitted beams while rotating the fast and slow axes of the beams by 90°, such that the slow axis of each emitted beam is perpendicular to the WBC dimension downstream of the microlens assembly. The microlens assembly also converges the chief rays of the emitters from each diode bar 405 toward a dispersive element 410. Suitable microlens assemblies are described in U.S. Pat. No. 8,553,327, filed on Mar. 7, 2011, and U.S. Pat. No. 9,746,679, filed on Jun. 8, 2015, the entire disclosure of each of which is hereby incorporated by reference herein.

As shown in FIG. 4, resonator 400 also features a set of SAC lenses (or “slow-axis collimators”) 415, one SAC lens 415 associated with, and receiving beams from, one of the diode bars 405. Each of the SAC lenses 415 collimates the slow axes of the beams emitted from a single diode bar 405. After collimation in the slow axis by the SAC lenses 415, the beams propagate to a set of interleaving mirrors 420, which redirect the beams toward the dispersive element 410. The arrangement of the interleaving mirrors 420 enables the free space between the diode bars 405 to be reduced or minimized, and also reduces or minimizes the overall wavelength locking bandwidth. Upstream of the dispersive element 410 (which may include, consist essentially of, or consist of, for example, a diffraction grating such as the transmissive diffraction grating depicted in FIG. 4), a lens 425 may optionally be utilized to collimate the sub-beams (i.e., emitted rays other than the chief rays) from the diode bars 405. In various embodiments, the lens 425 is disposed at an optical distance away from the diode bars 405 that is substantially equal to the focal length of the lens 425. Note that, in various embodiments, the overlap of the chief rays at the dispersive element 410 is primarily due to the redirection of the interleaving mirrors 420, rather than the focusing power of the lens 425.

Also depicted in FIG. 4 are lenses 430, 435, which form an optical telescope for mitigation of optical cross-talk, as disclosed in U.S. Pat. No. 9,256,073, filed on Mar. 15, 2013, and U.S. Pat. No. 9,268,142, filed on Jun. 23, 2015, the entire disclosure of which is hereby incorporated by reference herein. Resonator 400 may also include one or more folding mirrors 440 for redirection of the beams such that the resonator 400 may fit within a smaller physical footprint. The dispersive element 410 combines the beams from the diode bars 405 into a single, multi-wavelength beam, which propagates to a partially reflective output coupler 445. The coupler 445 transmits a portion of the beam as the output beam of resonator 400 while reflecting another portion of the beam back to the dispersive element 410 and thence to the diode bars 405 as feedback to stabilize the emission wavelengths of each of the beams.

In accordance with embodiments of the invention, the resonator locking wavelengths of the emitters 405 may be altered via adjustment of the folding angle of the folding mirror 440. As shown in FIG. 4, one or more actuators 450 may be utilized to tune the locking wavelengths of the emitters by altering the mirror folding angle, i.e., the angle at which the folding mirror 440 intercepts and redirects the beams toward the output coupler 445. In various embodiments, the angle and position of the output coupler 445 remain unchanged, and therefore the pointing of the output beam remains unchanged even as the folding mirror 440 (and the resulting operating/locking emitter wavelengths) are adjusted. However, the resonator output beam may be shifted in position at the output coupler 445 in the WBC dimension. In order to reduce or minimize this output beam position shift, the folding mirror 440 may be positioned as closely as possible to the dispersive element 410, either upstream or downstream thereof. For example, the distance between the folding mirror 440 and the dispersive element 410 may be less than 300 mm, less than 200 mm, less than 100 mm, or less than 75 mm. In various embodiments, the distance between the folding mirror 440 and the dispersive element may be at least 20 mm, at least 30 mm, at least 40 mm, or at least 50 mm. In various embodiments, in order to accommodate the output beam position shift on the output coupler 445, the output coupler 445 may be sufficiently large, at least in the WBC dimension. For example, the output coupler 445 may have a size greater than the expected output beam position shift by at least a factor of 50, at least a factor of 20, or at least a factor of 10. In such embodiments, any possible distortion or edge-effect-related to the output coupler 445 will not affect the beam, despite the position shift. In various embodiments, the output coupler 445 may have a size (e.g., diameter) of at least 8 mm, at least 10 mm, at least 12 mm, at least 14 mm, at least 16 mm, at least 18 mm, or at least 20 mm. The size of the output coupler 445 may be, in various embodiments, at most 50 mm, at most 40 mm, or at most 30 mm.

In various embodiments, the one or more actuators 450 may be responsive to, and thus controlled by, a controller (or “control system”) 455. The controller 455 may be provided as either software, hardware, or some combination thereof. For example, the system may be implemented on one or more conventional server-class computers, such as a PC having a CPU board containing one or more processors such as the Pentium or Celeron family of processors manufactured by Intel Corporation of Santa Clara, Calif., the 680x0 and POWER PC family of processors manufactured by Motorola Corporation of Schaumburg, Ill., and/or the ATHLON line of processors manufactured by Advanced Micro Devices, Inc., of Sunnyvale, Calif. The processor may also include a main memory unit for storing programs and/or data relating to the methods described herein. The memory may include random access memory (RAM), read only memory (ROM), and/or FLASH memory residing on commonly available hardware such as one or more application specific integrated circuits (ASIC), field programmable gate arrays (FPGA), electrically erasable programmable read-only memories (EEPROM), programmable read-only memories (PROM), programmable logic devices (PLD), or read-only memory devices (ROM). In some embodiments, the programs may be provided using external RAM and/or ROM such as optical disks, magnetic disks, as well as other commonly used storage devices. For embodiments in which the functions are provided as one or more software programs, the programs may be written in any of a number of high level languages such as PYTHON, FORTRAN, PASCAL, JAVA, C, C++, C #, BASIC, various scripting languages, and/or HTML. Additionally, the software may be implemented in an assembly language directed to the microprocessor resident on a target computer; for example, the software may be implemented in Intel 80x86 assembly language if it is configured to run on an IBM PC or PC clone. The software may be embodied on an article of manufacture including, but not limited to, a floppy disk, a jump drive, a hard disk, an optical disk, a magnetic tape, a PROM, an EPROM, EEPROM, field-programmable gate array, or CD-ROM.

In various embodiments, the controller 455 may also be utilized to control the flow of power (e.g., current) to the emitters 405 in order to, for example, apply simmer current and/or overdrive current thereto, as described above. The controller 455 may also be utilized to control local heaters (not shown in FIG. 4) utilized to apply heat to one or more of the emitters 405 (e.g., at or before cold start). In various embodiments, each emitter 405 may be associated with a separate local heater, or one local heater may be shared by two or more (or even all) of the emitters 405.

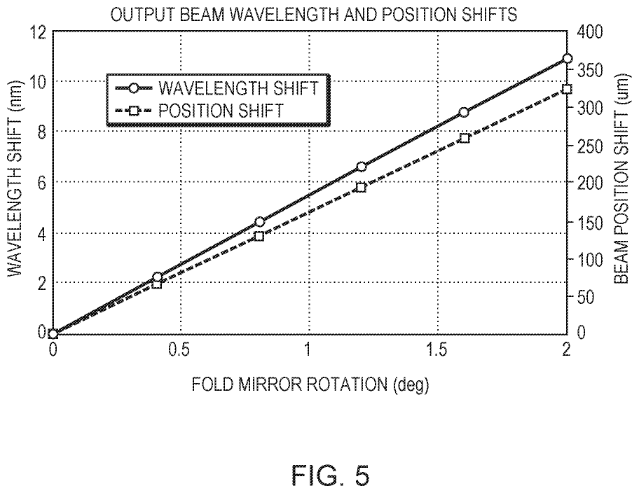

FIG. 5 is a graph of simulated wavelength and position shifts of the resonator output beam for an example resonator similar to resonator 400 as a function of the rotation angle of the folding mirror. In the example of FIG. 5, the resonator features a transmissive diffraction grating having a line density of 3.5/μm, a resonator center wavelength of about 418 nm, a folding mirror located about 85 mm downstream of the grating, and a telescopic lens pair (i.e., equivalent to lenses 430, 435 in FIG. 4) having a focal length ratio of about 18. As shown in FIG. 5, as the rotation angle of the folding mirror is increased, both the locking wavelength and the position of the beam on the output coupler (in the WBC dimension) shift accordingly. In this manner, the operating wavelength may be adjusted during emitter operation to fall within the gain bandwidth of the emitter, even as it changes as a function of operating temperature, over the entire temperature range from “cold status” to “hot status.”

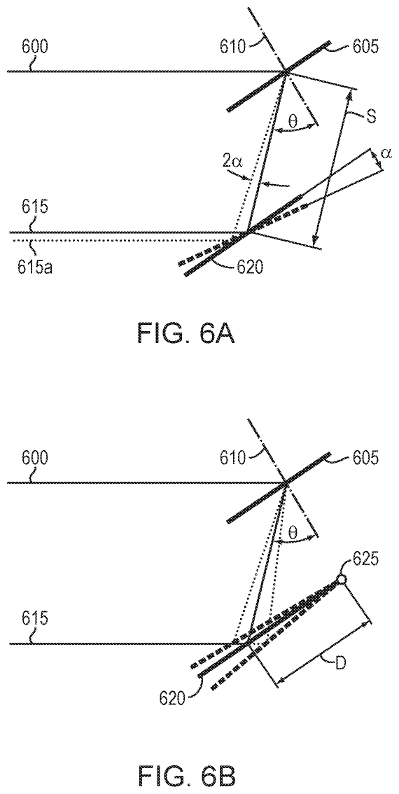

FIG. 6A schematically depicts the effect of folding mirror rotation on beam position. In FIG. 6A, beam 600 represents the chief ray of the center emitter in a WBC resonator propagating to a diffraction grating 605, where line 610 represents the normal to the grating 605. The resulting output (from the grating) beam 615 propagates to the output coupler (not shown) after being redirected by a folding mirror 620 (like folding mirror 440 of FIG. 4). For simplicity, the mirror 620 is depicted as arranged such that the output beam (or “resonator beam”) 615 is parallel to the incoming center chief ray 600; however, embodiments of the invention may be utilized to redirect output beams at other trajectories, as long as the output coupler is positioned to intercept the output beam accordingly. The output beam is typically normal to the feedback surface, i.e., the output coupler. As shown in FIG. 6A, rotating the mirror 620 by an angle α alters the resonator beam propagation downstream of the grating 605 by an angle 2α, and both the wavelength and the position of the resonator beam will be altered, as indicated by the line 615a in FIG. 6A. The wavelength shift Δλ is, in various embodiments, approximately equal to 2α×cos(θ)/p, where p is the line density of the grating 605. This equation generally applies to embodiments in which there are no optics having optical power (i.e., lens power) in the WBC dimension disposed between the grating 605 and the output coupler. The wavelength shift in the example of FIG. 5, which is based on a resonator similar to that of FIG. 4, is about 25% smaller than the value that would be calculated from the above equation because of the presence of the telescope lens pair 430, 435, both of which have lens power in the WBC dimension.

In various embodiments, the beam shift δS at the output coupler may be approximately equal to 2α×S/F, where S is the separation distance between the mirror 620 and the grating 605, and F is the beam size shrinkage factor in the WBC dimension caused by the telescopic lens pair (if present). The position shifts depicted in FIG. 5 result from a beam size shrinkage factor F of 18, which is equal to the focal length ratio of the lens pair.

In various embodiments of the invention, the position shift of the output beam at the output coupler may be reduced or minimized by adjusting the rotation axis of the folding mirror. FIG. 6B schematically depicts the reduction of beam shift of the output beam 615 via movement of the mirror rotation axis 625 a distance D away from the position at which the beam strikes the mirror 620. In various embodiments, the distance D is approximately equal to 2S×cos(θ)/sin(2θ). In this manner, as shown in FIG. 6B, the position shift of the output beam relative to the output coupler may be kept substantially constant, even as its operating wavelength changes due to rotation of the folding mirror 620.

In various embodiments of the invention, the resonator locking wavelength may also be adjusted by decentering one or more lenses in the WBC dimension. Such lenses include, but are not limited to, for example, lenses 425, 430, 435 in resonator 400 depicted in FIG. 4. Thus, in various embodiments of the invention, one or more lenses in a laser resonator, such as lenses 425, 430, 435, are configured to be decentered (i.e., translated) at least in the WBC dimension of the resonator. For example, the lenses may be coupled to one or more actuators configured to translate the lenses, and the one or more actuators may be responsive to the controller (e.g., as detailed above with respect to FIG. 4). The controller may be configured to decenter one or more of the lenses and translate the lenses during operation (and concomitant heating) of the emitters such that the lenses are centered in the WBC dimension when the emitters have reached their nominal operating temperatures. The induced wavelength shift will be proportional to δd/f, where δd is the lens decentering distance and f is the focal length of the lens. In various embodiments, lens decentering may not be preferred due to it requiring relatively larger adjustments than the mirror rotation adjustment of FIGS. 6A and 6B. Lens decentering may also induce larger beam position shifts relative to the output coupler, which may thus be more challenging to compensate for.

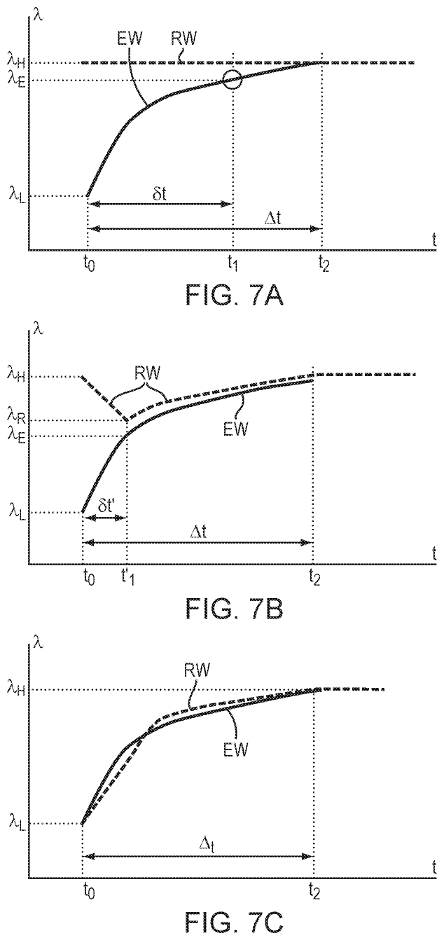

FIGS. 7A-7C schematically depict the relationship between resonator wavelength RW and emitter wavelength EW at cold start in accordance with various embodiments of the present invention. Specifically, FIG. 7A depicts the relationship between the optimized resonator locking wavelength RW and the emitter working wavelength EW at various times during the startup period of a WBC resonator without any adjustment of the working wavelength. For FIG. 7A, it is assumed, as is typical, that the WBC laser system is optimized at the emitter wavelength when in “hot status,” denoted in FIG. 7A as λ_{H}. It is also assumed, for simplicity, that the driving current is applied to the emitters at time to instantly. The emitter wavelength represented by the EW curve may represent the peak wavelength, the central wavelength, or any other wavelength within the emitter effective bandwidth (i.e., B in FIGS. 1A-1C). It is also assumed that the emitter junction temperature will quickly rise to an intermediate level within the first fraction of a second (or even less than a millisecond) and then relatively slowly rise to the final temperature representative of operation at “hot status.” The EW curve, starting from the “cold status” wavelength XL and ending at the “hot status” wavelength λ_{H}, is assumed to follow the same trend as the rise in emitter temperature. Depending on the thermal constant of the entire emitter, the entire duration Δt=t₂−t₀ of emitter temperature rise or, equivalently, emitter gain wavelength shift, may take more than a second, more than 2 seconds, more than 5 seconds, or longer. In various embodiments, this duration may be less than 60 seconds, less than 30 seconds, or less than 10 seconds, for example.

If the emitter bandwidth is very narrow, for example in the case depicted in FIG. 1C, the WBC laser will exhibit a very slow cold start, because it will not produce resonator power above an effective level until, at time t₁ in FIG. 7A, the emitter has attained a sufficiently high temperature so that the difference of emitter wavelength λ_{E}, and the preset resonator locking wavelength λ_{H} becomes smaller than the emitter effective bandwidth B, i.e., until (λ_{H}−λ_{E})<B. Application of simmer current and/or overdrive current, as depicted in FIGS. 2A-2C, will effectively move the EW curve closer to the RW curve at an earlier time, thereby reducing the laser startup time δt. However, as mentioned above, such techniques may be insufficient in embodiments in which emitters have very narrow gain bandwidths, e.g., various visible-light (e.g., blue, blue-violet, or violet) and/or ultraviolet-light emitters. Thus, instead of or in addition to moving the EW curve via application of simmer current and/or overdrive current, embodiments of the invention effectively lower the RW curve by altering the resonator locking wavelength as a function of time during startup from cold start. Various such embodiments are schematically depicted in FIGS. 7B and 7C.

FIG. 7B schematically depicts an embodiment in which the WBC resonator is initially optimized at the emitter “hot status” wavelength λ_{H}, and in which the resonator wavelength may be adjusted as described above in relation to FIGS. 4, 6A, and 6B. As shown, the adjustment of the resonator wavelength RW will not alter the behavior of the emitter wavelength EW during the time period Δt, which will follow the same curve as in FIG. 7A. In the embodiment of FIG. 7B, the actuator 414 is activated at time t₀ to start rotating the folding mirror 440 and is calibrated so that the resonator wavelength is quickly shifted down from λ_{H} to λ_{R}, which is an intermediate wavelength approaching the emitter wavelength λ_{E}. After the time t′₁, the resonator wavelength is adjusted to follow the EW curve until the hot status wavelength is attained. In embodiments in which the difference between λ_{R} and λ_{E} is smaller than the emitter effective bandwidth B, the laser rising time will be about δt′, which is shorter than the nominal rise time δt in FIG. 7A.

In such embodiments, the laser rise time is limited by, at least in part, the response time of the actuator rotating the folding mirror and the required maximum rotation. In an exemplary embodiment, the wavelength shift rate is about 0.1 nm/degree, and the emitter junction temperature may rise over 70°; therefore, the full wavelength shift at cold start will be around 7 nm, which corresponds to a 1.2° rotation of the mirror 440 of FIG. 4 in the embodiment of FIG. 5. Assuming, in an exemplary embodiment, that the emitter will complete a 30% shift of the total range during the actuator response period (e.g., in a time period in the sub-millisecond range), then the required wavelength adjustment will be about 5 nm, or about 4.5 nm if considering about 1 nm full bandwidth at 90% for the emitter, which corresponds to a minimum mirror tilt of about 0.8° in the embodiment of FIG. 4. Further assuming the actuator contact point on the mirror 440 is 10 mm away from the mirror rotating axis (for example the axis 625 shown in FIG. 6B), then the minimum actuator displacement will be 140 μm. Utilizing as an example a Thorlabs off-the-shelf piezo actuator (P#PK2F SF1), which has a 220 μm free stroke with 1 kHz no-load or about 330 Hz loaded resonant frequency, the minimum response time of the actuator for 140 μm displacement is estimated to be 640 μs.

FIG. 7C schematically depicts an embodiment in which the laser rise time from cold start is further minimized. In the embodiment of FIG. 7C, the resonator wavelength is adjusted to conform to the emitter “cold” wavelength at the initiation of the cold start. Such embodiments may be accomplished via two different techniques. First, the resonator wavelength may be initially optimized (i.e., with no mirror rotation) at the wavelength corresponding to the emitter “hot status.” Then, before cold start at time to, the actuator is preset so that the resonator locking wavelength is pre-shifted to the emitter “cold status” wavelength. The actuator is also calibrated to follow the emitter wavelength curve EW by gradually decreasing the rotation angle until the “hot status” wavelength is achieved at time t₂. Alternatively, the resonator wavelength may be optimized at the wavelength corresponding to the emitter “cold status,” and the actuator is calibrated to follow the emitter wavelength curve EW by gradually increasing the mirror rotation angle until the “hot status” wavelength is achieved at time t₂.

In contrast with the embodiment depicted in FIG. 7B, no abrupt change in resonator wavelength is required in the embodiment of FIG. 7C, and the rise time primarily depends on the drive current rise time rather than being limited by the actuator response time. The rise time of drive current for high-power diodes may be on the order of a few tens of microseconds or less. This greatly relaxed requirement on the actuator response time enables less-responsive means of adjusting resonator wavelength to be utilized, such as stepper motors and/or local heaters.

In various embodiments, the power of the WBC resonator may be further stabilized utilizing a feedback loop incorporated with the one or more actuators (via the controller) or other wavelength-adjustment means. For example, the resonator output power may be detected and utilized as a feedback signal to adjust the resonator locking wavelength to maximize output power. Such embodiments, as well as all embodiments of the invention detailed herein, may be utilized at times other than startup of the laser system from cold start. For example, the resonator wavelength may be advantageously adjusted to increase resonator power at later stages of laser emitter lifetime when the emitters become less efficient (i.e., operate at higher temperatures for the same driving current). In addition, “cold start,” as utilized herein, is not limited to the very initial startup of laser operation. Rather, cold start may also include the initiation of one or more (or even each) pulse when the laser system is being operated in pulsed mode, particularly when operating at short-duration pulses, when the emitters may always be operating near or at their “cold status.”

In various embodiments, the calibration of the wavelength adjustment (e.g., to follow the emitter wavelength curves in FIGS. 7B and 7C) may be accomplished via laboratory trials measuring startup time from cold start as a function of, e.g., mirror rotation. In addition or instead, the controller may be programmed to match the trend of wavelength shift predicted by thermal models of emitter temperature over time. Lookup tables and/or models may be generated to predict the initial emitter temperature status (e.g., cold, hot, or an intermediate temperature) of the emitter at each “cold start” based on operating modes and settings of the laser system (e.g., current level, pulse rate and duration, flow rate of cooling fluid, etc.) A feedback loop based on emitter temperature (measured by, e.g., thermistors or other temperature sensors) may also be incorporated into embodiments of the invention. Such calibration, feedback, and programming may be accomplished by those of skill in the art without undue experimentation.

After the optimized cold start of laser systems in accordance with embodiments of the present invention, the output beams of the laser systems may be propagated to a delivery optical fiber (which may be coupled to a laser delivery head) and/or utilized to process a workpiece. In various embodiments, a laser head contains one or more optical elements utilized to focus the output beam onto a workpiece for processing thereof. For example, laser heads in accordance with embodiments of the invention may include one or more collimators (i.e., collimating lenses) and/or focusing optics (e.g., one or more focusing lenses). A laser head may not include a collimator if the beam(s) entering the laser head are already collimated. Laser heads in accordance with various embodiments may also include one or more protective window, a focus-adjustment mechanism (manual or automatic, e.g., one or more dials and/or switches and/or selection buttons). Laser heads may also include one or more monitoring systems for, e.g., laser power, target material temperature and/or reflectivity, plasma spectrum, etc. A laser head may also include optical elements for beam shaping and/or adjustment of beam quality (e.g., variable BPP) and may also include control systems for polarization of the beam and/or the trajectory of the focusing spot. In various embodiments, the laser head may include one or more optical elements (e.g., lenses) and a lens manipulation system for selection and/or positioning thereof for, e.g., alteration of beam shape and/or BPP of the output beam, as detailed in U.S. patent application Ser. No. 15/188,076, filed on Jun. 21, 2016, the entire disclosure of which is incorporated by reference herein. Exemplary processes include cutting, piercing, welding, brazing, annealing, etc. The output beam may be translated relative to the workpiece (e.g., via translation of the beam and/or the workpiece) to traverse a processing path on or across at least a portion of the workpiece.

In embodiments an optical delivery fiber, the optical fiber may have many different internal configurations and geometries. For example, the optical fiber may include, consist essentially of, or consist of a central core region and an annular core region separated by an inner cladding layer. One or more outer cladding layers may be disposed around the annular core region. Embodiments of the invention may incorporate optical fibers having configurations described in U.S. patent application Ser. No. 15/479,745, filed on Apr. 5, 2017, and U.S. patent application Ser. No. 16/675,655, filed on Nov. 6, 2019, the entire disclosure of each of which is incorporated by reference herein.

In various embodiments, the controller may control the motion of the laser head or output beam relative to the workpiece via control of, e.g., one or more actuators. The controller may also operate a conventional positioning system configured to cause relative movement between the output laser beam and the workpiece being processed. For example, the positioning system may be any controllable optical, mechanical or opto-mechanical system for directing the beam through a processing path along a two- or three-dimensional workpiece. During processing, the controller may operate the positioning system and the laser system so that the laser beam traverses a processing path along the workpiece. The processing path may be provided by a user and stored in an onboard or remote memory, which may also store parameters relating to the type of processing (cutting, welding, etc.) and the beam parameters necessary to carry out that processing. The stored values may include, for example, beam wavelengths, beam shapes, beam polarizations, etc., suitable for various processes of the material (e.g., piercing, cutting, welding, etc.), the type of processing, and/or the geometry of the processing path.

As is well understood in the plotting and scanning art, the requisite relative motion between the output beam and the workpiece may be produced by optical deflection of the beam using a movable mirror, physical movement of the laser using a gantry, lead-screw or other arrangement, and/or a mechanical arrangement for moving the workpiece rather than (or in addition to) the beam. The controller may, in some embodiments, receive feedback regarding the position and/or processing efficacy of the beam relative to the workpiece from a feedback unit, which will be connected to suitable monitoring sensors.

In addition, the laser system may incorporate one or more systems for detecting the thickness of the workpiece and/or heights of features thereon. For example, the laser system may incorporate systems (or components thereof) for interferometric depth measurement of the workpiece, as detailed in U.S. patent application Ser. No. 14/676,070, filed on Apr. 1, 2015, the entire disclosure of which is incorporated by reference herein. Such depth or thickness information may be utilized by the controller to control the output beam to optimize the processing (e.g., cutting, piercing, or welding) of the workpiece, e.g., in accordance with records in the database corresponding to the type of material being processed.

The terms and expressions employed herein are used as terms of description and not of limitation, and there is no intention, in the use of such terms and expressions, of excluding any equivalents of the features shown and described or portions thereof, but it is recognized that various modifications are possible within the scope of the invention claimed.

1. A method of operating a wavelength-beam-combining (WBC) resonator, wherein the WBC resonator comprises an emitter having (i) a gain bandwidth defining a range of operating wavelengths at which a gain of the emitter exceeds a predetermined effective gain level, and (ii) a nominal operating wavelength (a) falling within the gain bandwidth at an operating temperature and (b) falling outside of the gain bandwidth at a startup temperature lower than the operating temperature, the method comprising:
providing the emitter having a temperature equal to the startup temperature;
applying heat to the emitter to increase the temperature thereof; and
thereafter, operating the emitter to emit a beam at the nominal operating wavelength, whereby the temperature of the emitter increases to the operating temperature during operation.

2. The method of claim 1, wherein (i) operating the emitter comprises applying to the emitter a current greater than a lasing threshold current of the emitter, and (ii) applying heat to the emitter comprises applying to the emitter a simmer current less than the lasing threshold current.

3. The method of claim 1, wherein applying heat to the emitter comprises locally heating the emitter via a heat source external to the emitter.

4. The method of claim 3, wherein the heat source comprises at least one of a resistive heater, an infrared heater, or a thermoelectric heater.

5. The method of claim 1, wherein the nominal operating wavelength of the emitter is a wavelength of visible light or ultraviolet light.

6. The method of claim 1, wherein the nominal operating wavelength of the emitter is a wavelength of blue light.

7. The method of claim 1, wherein the startup temperature is approximately equal to a temperature of an ambient environment in which the WBC resonator is disposed.

8. The method of claim 1, wherein (i) the WBC resonator comprises a cooling system utilizing a fluid coolant, and (ii) the startup temperature is approximately equal to a temperature of the fluid coolant.

9. The method of claim 1, wherein the WBC resonator comprises:
a plurality of additional emitters each having a nominal operating wavelength different from the nominal operating wavelength of the emitter;
a dispersive element configured to receive beams emitted by the emitter and the plurality of additional emitters and combine the beams into a multi-wavelength beam; and
disposed optically downstream of the dispersive element, a partially reflective output coupler configured to (i) receive the multi-wavelength beam, (ii) transmit a first portion of the multi-wavelength beam from the WBC resonator as an output beam, and (iii) reflect a second portion of the multi-wavelength beam back toward the dispersive element.

10. The method of claim 1, further comprising:
combining, within the WBC resonator, the beam emitted by the emitter with beams emitted by a plurality of additional emitters, to thereby form a multi-wavelength beam;
transmitting a first portion of the multi-wavelength beam from the WBC resonator as an output beam; and
propagating a second portion of the multi-wavelength beam back to the emitter and the plurality of additional emitters to stabilize the beams emitted by the emitter and by the plurality of additional emitters.

11. The method of claim 10, further comprising applying heat to the plurality of additional emitters to increase a temperature thereof, and, thereafter, operating the plurality of additional emitters to emit beams therefrom.

12. The method of claim 10, further comprising processing a workpiece with the output beam.

13. The method of claim 12, wherein processing the workpiece comprises at least one of cutting, welding, etching, annealing, drilling, soldering, or brazing.

14. The method of claim 12, wherein processing the workpiece comprises physically altering at least a portion of a surface of the workpiece.

15. A method of operating a wavelength-beam-combining (WBC) resonator, wherein (A) the WBC resonator comprises an emitter having (i) a gain bandwidth defining a range of operating wavelengths at which a gain of the emitter exceeds a predetermined effective gain level, and (ii) a nominal operating wavelength (a) falling within the gain bandwidth at an operating temperature and (b) falling outside of the gain bandwidth at a startup temperature lower than the operating temperature, and (B) the emitter is operable at a nominal drive current greater than a lasing threshold current to produce a beam having the nominal operating wavelength, the method comprising:
initiating operation of the emitter, at the startup temperature, by applying to the emitter an overdrive current greater than the nominal drive current; and
when a temperature of the emitter increases to the operating temperature, decreasing the applied current to the nominal drive current.

16. The method of claim 15, wherein the applied current is decreased gradually from the overdrive current to the nominal drive current as the temperature of the emitter increases to the operating temperature.

17. The method of claim 15, further comprising, before initiating operation of the emitter, applying heat to the emitter to increase the temperature thereof.

18. The method of claim 17, wherein applying heat to the emitter comprises applying to the emitter a simmer current less than the lasing threshold current.

19. The method of claim 17, wherein applying heat to the emitter comprises locally heating the emitter via a heat source external to the emitter.

20. The method of claim 19, wherein the heat source comprises at least one of a resistive heater, an infrared heater, or a thermoelectric heater.

21. The method of claim 15, wherein the nominal operating wavelength of the emitter is a wavelength of visible light or ultraviolet light.

22. The method of claim 15, wherein the nominal operating wavelength of the emitter is a wavelength of blue light.

23. The method of claim 15, wherein the WBC resonator comprises:
a plurality of additional emitters each having a nominal operating wavelength different from the nominal operating wavelength of the emitter;
a dispersive element configured to receive beams emitted by the emitter and the plurality of additional emitters and combine the beams into a multi-wavelength beam; and
disposed optically downstream of the dispersive element, a partially reflective output coupler configured to (i) receive the multi-wavelength beam, (ii) transmit a first portion of the multi-wavelength beam from the WBC resonator as an output beam, and (iii) reflect a second portion of the multi-wavelength beam back toward the dispersive element.

24. The method of claim 15, further comprising:
combining, within the WBC resonator, the beam emitted by the emitter with beams emitted by a plurality of additional emitters, to thereby form a multi-wavelength beam;
transmitting a first portion of the multi-wavelength beam from the WBC resonator as an output beam; and
propagating a second portion of the multi-wavelength beam back to the emitter and the plurality of additional emitters to stabilize the beams emitted by the emitter and by the plurality of additional emitters.

25. The method of claim 24, further comprising processing a workpiece with the output beam.

26. The method of claim 25, wherein processing the workpiece comprises at least one of cutting, welding, etching, annealing, drilling, soldering, or brazing.

27. The method of claim 25, wherein processing the workpiece comprises physically altering at least a portion of a surface of the workpiece.

28.-89. (canceled)
